(19) United States
(12) Patent Application Publication
(10) Pub. No.: US 2025/0338592 A1
(43) Pub. Date: Oct. 30, 2025

(54) LDMOS DEVICES WITH FLOATING FIELD PLATE

(71) Applicant: Texas Instruments Incorporated, Dallas, TX (US)

(72) Inventors: Jingjing Chen, San Jose, CA (US); Dhanoop Varghese, Plano, TX (US); Bikram Kishore Mahajan, Richardson, TX (US); Xiaochuan Bi, Saratoga, CA (US)

(21) Appl. No.: 18/650,394

(22) Filed: Apr. 30, 2024

(51) Int. Cl. H01L 29/40; H01L 21/762; H01L 29/66; H01L 29/78

(52) U.S. Cl. CPC H10D 64/111; H01L 21/7621; H10D 30/0285; H10D 30/65

(57) ABSTRACT

A semiconductor device includes a semiconductor layer over a semiconductor substrate with a body region and a drain drift region of opposite first and second conductivity types, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, a field relief dielectric layer over the drain drift region, the field relief dielectric layer extending from the gate dielectric layer toward the drain region and having a thickness greater than the gate dielectric layer, and a floating field plate over the field relief dielectric layer and between the gate electrode and the drain, the field plate spaced apart from the gate electrode.

### BACKGROUND

Drain extended transistors are used in high voltage applications that require high breakdown voltage ratings and efficient operation, such as a low side switch in a switching power supply to provide low source-drain resistance (RDSON) during the on state, along with the ability to block or withstand high off-state voltages between the drain and the source or gate. Scaling drain extended transistors to reduce the half pitch dimension can worsen channel hot carrier (CHC) injection and reduce linear mode drain current (Idlin) performance over time, leading to reduced device reliability.

### SUMMARY

In one aspect, a semiconductor device includes a semiconductor layer over a semiconductor substrate, the semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, a field relief dielectric layer over the drain drift region, the field relief dielectric layer extending from the gate dielectric layer toward the drain region and having a thickness greater than the gate dielectric layer, and a floating field plate located over the field relief dielectric layer and between the gate electrode and the drain region.

In another aspect, a semiconductor device includes a semiconductor layer over a semiconductor substrate, the semiconductor layer including a body region having a first conductivity type and a drain drift region having a second, opposite, conductivity type, a gate dielectric layer over the body region and extending over a junction between the body region and the drain drift region, a gate electrode over the gate dielectric layer, a drain region having the second conductivity type in the drain drift region, the drain region having a dopant density greater than a dopant density of the drain drift region, a field relief dielectric layer over the drain drift region, the field relief dielectric layer extending from the gate dielectric layer toward the drain region and having a thickness greater than the gate dielectric layer, and a field plate located over the field relief dielectric layer and between the gate electrode and the drain region, the field plate spaced apart from the gate electrode, wherein the field plate is not conductively connected to any other structure.

In a further aspect, a method of fabricating a semiconductor device includes forming a body region having a first conductivity type in a semiconductor layer over a semiconductor substrate, forming a field relief dielectric layer over the body region, forming a drain drift region having a second, opposite, conductivity type under the field relief dielectric layer, forming a gate dielectric layer over the body region and extending over a junction between the body region and the drain drift region, forming a polysilicon layer over the gate dielectric layer and over the field relief dielectric layer, patterning the polysilicon layer to form a gate electrode over the gate dielectric layer and a field plate located over the field relief dielectric layer and spaced apart from the gate electrode, implanting a source region and a drain region of the body region with dopants of the second conductivity type, and forming electrically conductive contacts to the gate electrode and to the source and drain regions without forming any electrical connection to the field plate.

### BRIEF DESCRIPTION OF THE DRAWINGS

FIG. 1 is a partial sectional side elevation view of a semiconductor device including a drain extended transistor with a floating drain field plate taken along line 1-1 in FIG. 1A.

FIG. 1A is a partial top plan view of the semiconductor device of FIG. 1.

FIG. 2 is a flow diagram of a method of fabricating a semiconductor device.

FIGS. 3-16 are partial sectional side elevation views of the semiconductor device of FIGS. 1 and 1A undergoing fabrication processing according to the method of FIG. 2.

FIG. 17 is a partial sectional side elevation view of the semiconductor device and corresponding interface trap carrier generation graphs for the drain field plate tied to drain voltage and floated.

FIGS. 18A and 18B are partial side 5% current flow line simulations of the drain extended transistor for transistor drain field plates tied to drain voltage and floated.

FIG. 19 is a partial side electrostatic potential simulation of a drain extended transistor with a drain field plate biased to the drain voltage.

FIG. 20 is a partial side electrostatic potential simulation of a drain extended transistor with a floating drain field plate.

FIG. 21 is a partial side impact ionization simulation of a drain extended transistor with a drain field plate biased to the drain voltage.

FIG. 22 is a partial side impact ionization simulation of a drain extended transistor with a floating drain field plate.

FIG. 23 is a graph of linear mode drain current shift for transistor drain field plates tied to drain voltage and floated.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

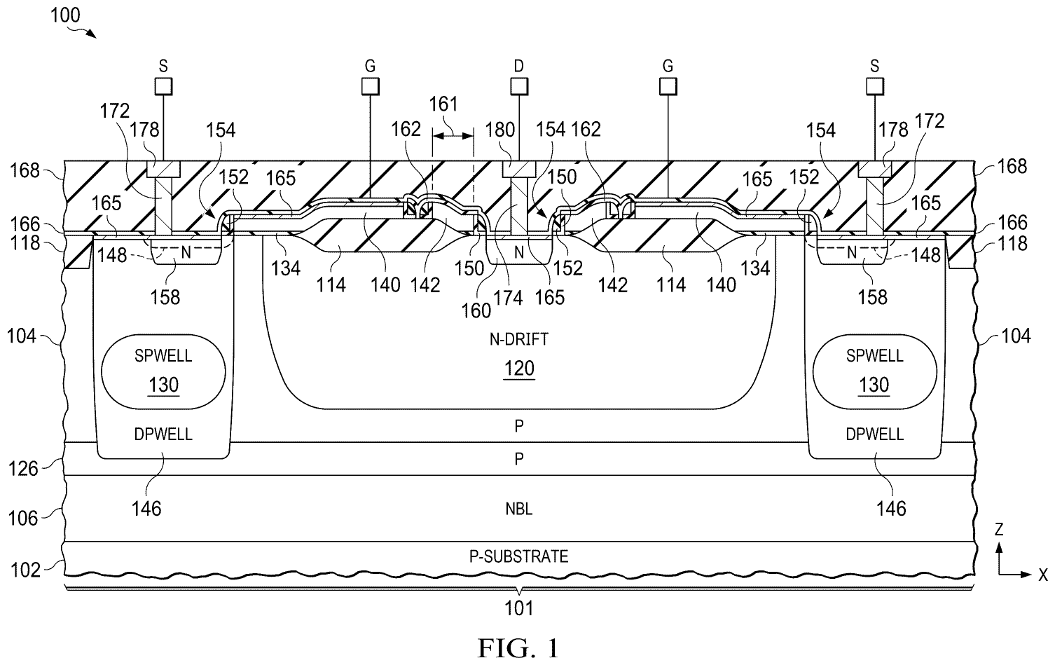

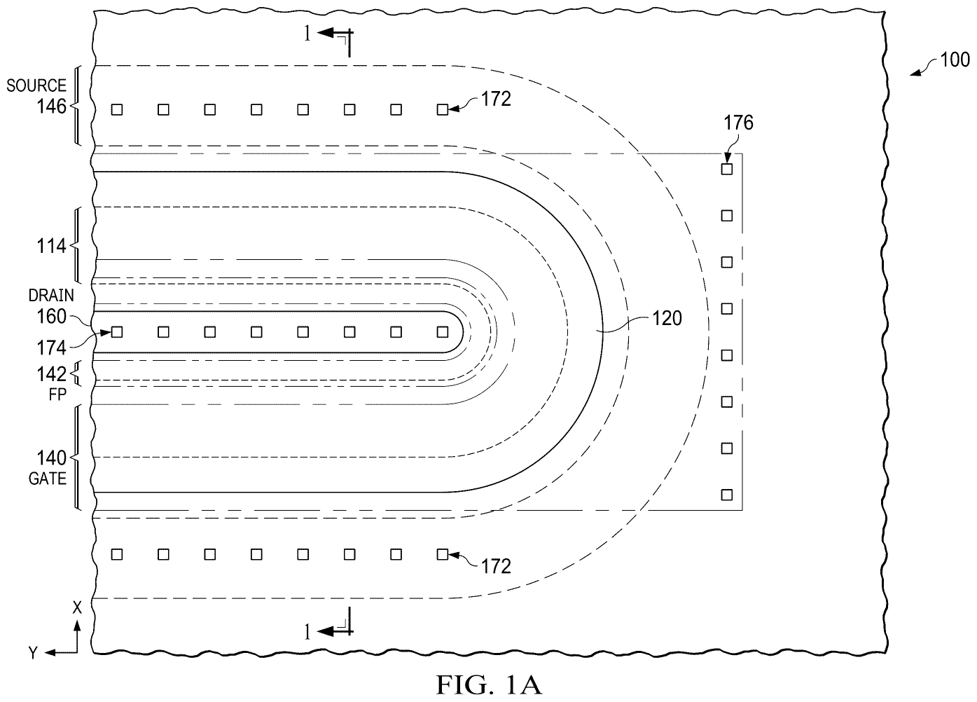

FIGS. 1 and 1A show a semiconductor device 100 including a drain extended transistor 101 with a floating field plate 142 (which may also be referred to as a floating drain field plate). The device 100 is illustrated in an example three-dimensional space with a first direction X (FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another.

The example transistor 101 is an n-channel laterally diffused metal oxide semiconductor (NMOS or NMOS LDMOS). P-channel metal oxide transistors (PMOS) LDMOS transistors can be formed when n-doped regions are substituted by p-doped regions and p-doped regions are substituted by n-doped regions in another implementation. The example device 100 includes a semiconductor substrate 102, such as including silicon or other semiconductor material from a starting wafer doped with impurities of a first conductivity type (e.g., P-type), such as a silicon (Si) or other semiconductor wafer (e.g., silicon carbide or SiC, gallium nitride or GaN, etc.), a silicon over insulator (SOI) wafer, etc.

A semiconductor layer 104 (e.g., p-type epitaxial silicon) extends over the semiconductor substrate 102 and includes a body region 104 having the first conductivity type (e.g., P-type). An n-type buried layer (NBL) 106 extends under the semiconductor layer 104 and has an opposite second conductivity type (e.g., N-type). The device 100 includes a field relief dielectric layer 114, such as a local oxidation of silicon (LOCOS) layer of silicon dioxide (SiO₂), and an isolation structure including shallow trench isolation silicon dioxide 118 extends around the outer periphery of the transistor 101 along and into the top side of the semiconductor layer 104.

A drain drift region 120 (e.g., labelled “N-DRIFT” in FIG. 1) has the second conductivity type and extends in the body region 104. The field relief dielectric layer 114 extends over the drain drift region 120. As shown in FIG. 1A, the transistor has a finger or racetrack shape with a center drain finger (e.g., labelled “D” in FIG. 1 and “DRAIN” in FIG. 1A), a gate (e.g., labelled “G” in FIG. 1 and “GATE” in FIG. 1A) that encircles the drain, and a source (e.g., labelled “S” in FIG. 1 and “SOURCE” in FIG. 1A) encircles the gate. In this or other examples, the transistor can include further drain-centered finger or racetrack structures (not shown). In these or other implementations, the transistor can include one or more source-centered finger or racetrack structures and/or one or more gate-centered finger or racetrack structures (not shown).

As further shown in FIG. 1, the example device 100 can also include a p-type buried layer 126 (e.g., labelled “PBL”, also referred to as a pRESURF layer for safe operating area (SOA) improvement) with the first conductivity type and a dopant concentration greater than the body region 104. The body region 104 of the semiconductor layer includes a shallow well 130 (e.g., labeled “SPWELL” in FIG. 1) below the source S, with the first conductivity type (e.g., p-type) and a dopant density higher than that of the body region 104. The shallow well 130 increases a base doping level of the body region 104 to suppress a parasitic lateral NPN bipolar transistor formed by N+ source-p-body-N+ drain D, which may limit high current operation for the LDMOS transistor 101, thus restricting the safe operating area (SOA) of the LDMOS transistor 101.

The transistor 101 also includes a gate dielectric layer 134 with a racetrack shape (FIG. 1A) that extends over a portion of the body region 104 (FIG. 1). The gate dielectric layer 134 extends over a junction between the body region 104 and the drain drift region 120. The gate dielectric layer 134 extends to outer bird's beak tapered portions of the field relief dielectric layer 114 and over the channel and an interface or junction between the p-type body region 104 and the n-type drift region 120 underneath a portion of the gate fingers or racetrack G. A polysilicon gate electrode 140 extends over the gate dielectric layer 134 and also over a portion of the field relief dielectric layer 114 above the drift region 120.

The transistor has a floating field plate 142, which may also be referred to as a drain field plate, which is located over the field relief dielectric layer 114. The floating field plate 142 in this example also has a racetrack shape (e.g., labelled “FP” in FIG. 1A) and the floating field plate 142 is laterally spaced apart from the gate electrode 140 and is positioned laterally between the gate electrode 140 and the transistor drain. The field plate 142 is not conductively connected to any other structure.

As shown in the example of FIG. 1A, the field plate 142 follows a path that has rounded corners with radii greater than a thickness (e.g., along the third direction Z) of the field plate 142. The field relief dielectric layer 114 in one example includes a local oxidation of silicon (LOCOS) layer of silicon dioxide, and the field plate 142 extends over a tapered edge of the field relief dielectric layer 114. In the illustrated example, the field plate 142 is located over a point (e.g., along the first direction X in FIG. 1) at which the LOCOS layer ends (e.g., where a bird's beak shape of the LOCOS field relief dielectric layer 114 begins) at a top surface of the semiconductor layer 104. In one example, the field plate 142 is or includes polycrystalline silicon and can be formed and patterned concurrently with the gate electrode 140.

The transistor 101 also includes a source with a p-type deep well region 146 having the first conductivity type (e.g., labelled “DPWELL” in FIG. 1) that extends through and below the p-type shallow well 130. The p-type deep well region 146 extends to the top side of the body region 104 and connects to the p-type buried layer 126. An n-type deep well (DWELL) region 148 extends along the top side of the p-type deep well region 146 and has the second conductivity type.

The device 100 includes sidewall spacer structures 154 along the lateral sides of the gate electrode 140 and the field plate 142. The sidewall spacers 154 in one example include an oxide layer 150 and a nitride layer 152 formed by deposition and anisotropic etching. The sidewall spacers 154 overlap an edge of the field relief dielectric layer 114 adjacent to a drain region. In another example, a nitride layer 152 may be deposited across the surface of the wafer and etched to form a nitride-only sidewall spacer 154. The transistor 101 has a source region 158 with the second conductivity type (N-type) in the deep well 146, where the source region 158 has a larger depth than the n-type DWELL region 148.

The transistor drain includes a drain region 160 with the second conductivity type (N-type) extending along and into the top side of the drain drift region 120 in the body region 104 and laterally encircled by the field plate 142. The field plate 142 is spaced apart from and extends laterally between the gate electrode 140 and the drain region 160. The field plate 142 is electrically floating with respect to (e.g., not conductively connected to) any terminal of the transistor 101 or to the substrate 102. The drain region 160 has a dopant density greater than the dopant density of the drain drift region 120. The field relief dielectric layer 114 extends from the gate dielectric layer 134 toward the drain region 160 and has a thickness greater than the gate dielectric layer 134. The field plate 142 is not conductively connected to any other structure and in operation is floating with respect to the terminals of the transistor 101 and with respect to the substrate 102. In one example, the field plate 142 extends laterally between the drain region 160 and the gate by a distance 161 (FIG. 1) that is at least twice the thickness along the third direction Z of the field relief dielectric layer 114.

The semiconductor device 100 in one example has a silicide blocking layer 162 covering an entire top side of the field plate 142. In one example, the silicide blocking layer is or includes one or more sublayers of an oxide, a nitride, an oxynitride, or combinations thereof. In the illustrated example, the silicide blocking layer 162 covers an entire top side of the field plate 142, and no conductive contacts are connected to the field plate 142. The field plate 142 is electrically isolated from the gate electrode 140 and from the drain region 160. In the illustrated example, wherein the gate electrode 140 extends over the field relief dielectric layer 114 and the gate electrode 140 is laterally spaced apart from the field plate 142 by a portion of the silicide blocking layer 162 that extends on the sidewall spacer structures. The silicide blocking layer 162 in one example extends over the entire top side of the field plate 142 and along the top and sides of the sidewall spacers between the field plate 142 and the gate electrode 140 as shown in FIG. 1. The sidewall spacer on the sidewall of the field plate 142 extends to the drain region 160.

The semiconductor device 100 also includes silicide layers 165 that extend along upper sides of the deep well region 146 of the source and of the drain region 160 to facilitate low resistance electrical connection to the source and drain terminals of the transistor 101. In addition, a metal silicide layer 165 can be provided for low resistance electrical connection to the gate by conductive metal (e.g., tungsten) contacts in a gate contact region at the lateral ends of the finger structure (FIG. 1A). The semiconductor device 100 also includes a nitride etch stop layer 166 that extends over portions of the metal silicide 165, the sidewall spacers 154, and the silicide blocking layer 162. The semiconductor device 100 can include a single or multilevel metallization structure, with a pre-metal dielectric 168 (PMD), conductive metal (e.g., tungsten) contacts 172 and 174 for the source and the drain (FIGS. 1 and 1A) and gate contacts 176 (FIG. 1A). The illustrated portion of the metallization structure in FIG. 1 also shows metal interconnects 178 and 180 conductively coupled to the respective source and drain contacts 172 and 174.

The extended drain of the transistor 101 provides a relatively lightly doped drift region to extend the high voltage drain away from the edge of the channel region and the planar drift region can be used to increase the reverse blocking voltage beyond the voltage rating of the gate oxide in a particular process. For even higher drain voltage rating, the drain side of the gate polysilicon is spaced from the drift region by the field relief dielectric layer 114 to facilitate more complete depletion of the drift region. Reduced surface field (RESURF) profiled doping can be used for full reverse bias depletion of the drift region. The drift region doping level or dopant concentration is preferably higher near the connection to the transistor channel region to mitigate channel hot carrier injection into the gate and enhance the transistor reliability.

In power switching circuits, such as DC-DC converters, a high-side switch and a low-side switch may be fabricated as drain extended transistors and a source/back gate terminal of the high-side device can be isolated from circuit ground to facilitate high-voltage operation. In addition, shrinking geometries and alignment tolerances of advanced semiconductor manufacturing processes increase the performance impact of non-uniformities such as center-edge differences in device structure locations. Scaling drain extended transistors to reduce the half pitch dimension can worsen channel hot carrier (CHC) injection and shift (e.g., reduce) linear mode drain current (Idlin) performance over time and may lead to reduced device reliability.

The floating field plate 142 advantageously mitigates channel hot carrier CHC Idlin shift without sacrificing device pitch and specific resistance Rsp of the transistor 101 and allows smaller half pitch dimensions while maintaining good breakdown voltage performance. CHC performance can be improved in other ways, for example, by increasing the spacing between the drain contacts 172 and the LOCOS field relief dielectric layer 114, for example, using a silicide blocking layer mask at the drain side. However, manufacturing design rules limitations inhibit the use of the silicide blocking layer mask to enhance CHC performance while reducing the half pitch dimensions of the transistor 101. Moreover, the use of the silicide blocking layer mask to increase the field relief dielectric spacing to the drain contact 172 increases the half pitch of the transistor 101 and can adversely affect the specific resistance Rsp.

In contrast, the floating field plate 142 at the drain side and extending beyond the tapered end (bird's beak) of the field relief dielectric layer 114 can help spread the drain voltage across the dielectric-semiconductor interface at the bottom of the field relief dielectric layer 114 while allowing reduction in the half pitch of the transistor 101 without significantly impacting the specific resistance Rsp. The floating drain field plate 142 can help move the drain silicide area and contact away from the drain and can serve as a hard mask to block drain implantation close to the LOCOS field relief dielectric layer 114.

The floating drain field plate 142 over a portion of the LOCOS field relief oxide layer 114 can be designed for a particular voltage rating LDMOS transistor 101 and can be implemented using polysilicon according to design rules associated with formation and patterning of a polysilicon gate electrode 140 with improved CHC benefits and reduced Idlin shift.

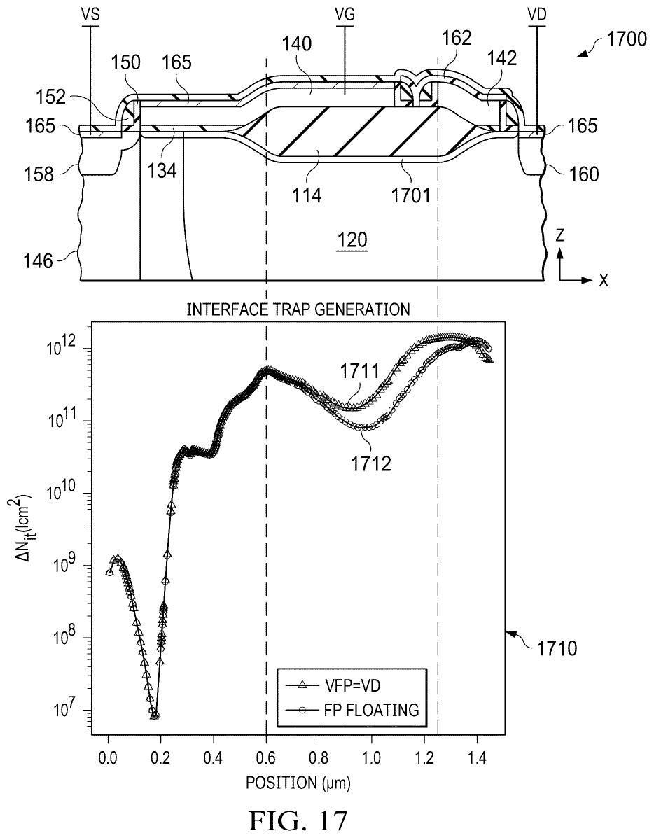

In addition, the floating field plate 142 provides advantages with respect to reduced channel hot carrier injection into the field relief dielectric layer 114 along the interface with the underlying drift region 120 without significantly adversely impacting breakdown voltage or specific resistance compared with biased field plate designs. In one example, an implementation of the LDMOS transistor 101 with a floating field plate 142 has a breakdown voltage improvement of approximately 2.5% and a specific resistance Rsp of approximately 1% compared to a similarly sized LDMOS transistor with a field plate biased at the drain potential. In addition, as discussed further below in connection with FIGS. 17-23, the floating field plate 142 mitigates CHC injection at the interface of the semiconductor material of the drift region 120 and the field relief dielectric 114, and thereby mitigates linear drain current (Idlin) shift and enhances device reliability.

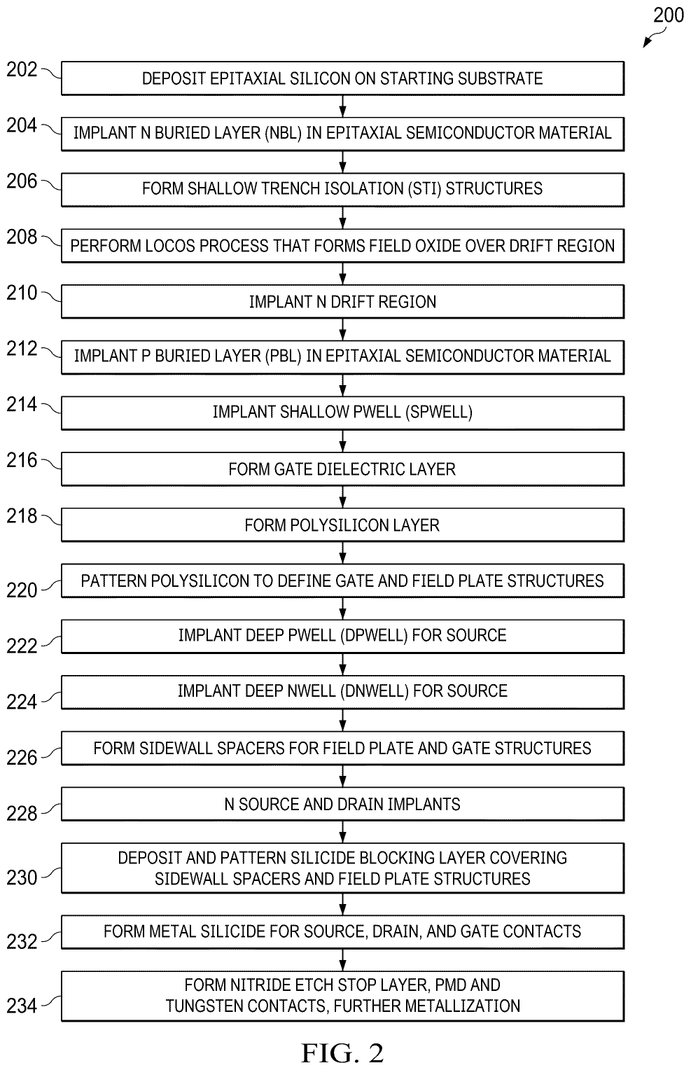

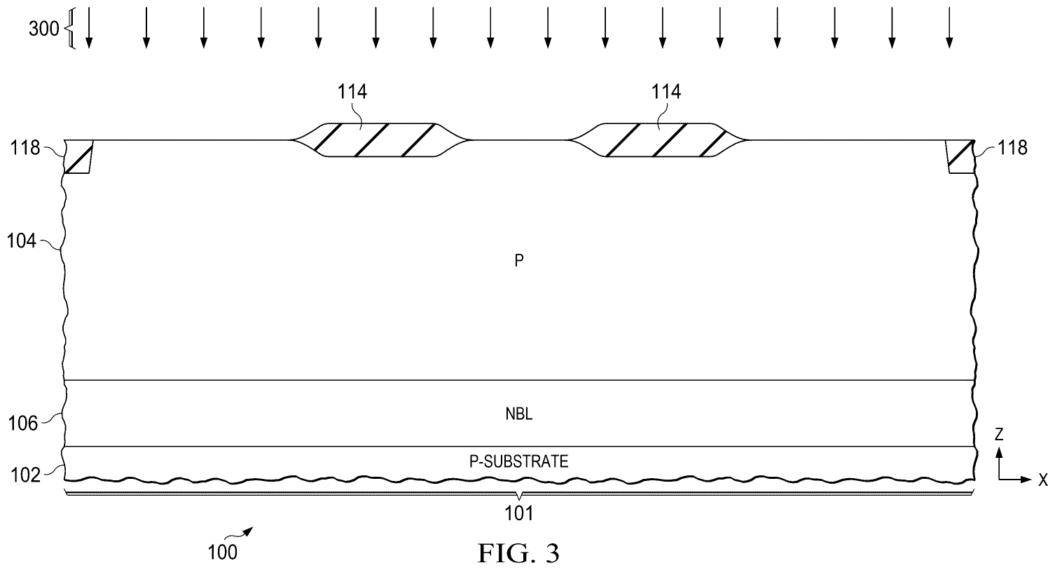

Referring also to FIGS. 2-16, FIG. 2 shows a method 200 of fabricating a semiconductor device and FIGS. 3-16 illustrate the example semiconductor device 100 of FIGS. 1 and 1A undergoing fabrication processing according to the method 200. In the following description, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), plasma enhanced CVD (PECVD), or atomic layer deposition (ALD), for example. As another example, silicon nitride may be a silicon-rich silicon nitride or an oxygen-rich silicon nitride. Silicon nitride may contain some oxygen, but not so much that the materials dielectric constant is substantially different from that of high purity stoichiometric silicon nitride. In addition, terms such as top, bottom, and under may be used in this disclosure, and such terms should not be construed as limiting the position or orientation of a structure or element but should be used to provide spatial relationship between structures or elements. Described examples include doped regions of various semiconductor structures which may be characterized as p-doped and/or n-doped regions or portions and include regions that have majority carrier dopants of a particular type, such as n-type dopants or p-type dopants.

The method 200 in one example includes forming a semiconductor layer on a starting substrate at 202 in FIG. 2, for example, by forming a semiconductor layer (e.g., epitaxial silicon) on the starting p-type substrate 102 of FIG. 1 above including forming the body region 104 having the first conductivity type (e.g., p-type) in the semiconductor layer over the semiconductor substrate 102. The method 200 in this example includes implanting n-type dopants or impurities (e.g., phosphorus, etc.) to form the n-type buried layer (NBL) 106 at 204 in FIG. 2. In other implementations, the NBL 106 and the processing at 204 can be omitted. In one example, the method 200 further includes forming isolation structures at 206, such as shallow trench isolation (STI) structures 118 as shown in FIGS. 1 and 3.

The method 200 in this example continues at 208 with forming the field relief dielectric layer 114 over the body region 104. FIG. 3 shows one example, in which the field relief dielectric layer 114 is formed by performing a local oxidation of silicon (LOCOS) process 300. In one example, a pad oxide layer (not shown) of silicon dioxide may be formed on the semiconductor layer, and the pad oxide layer may include silicon dioxide that is formed by a thermal oxidation process or a chemical vapor deposition (CVD) process. The pad oxide layer can help reduce stress between the semiconductor layer and subsequent layers, and the pad oxide layer can be 5 nm to 50 nm thick in one example. A silicon nitride layer (not shown) can be deposited and patterned, and a plasma etch process can be used to selectively remove the silicon nitride material to expose the epitaxial silicon in a prospective field relief portion of the top side of the semiconductor layer. A thermal process is performed, such as a furnace oxidation process 300 to form the field relief dielectric layer 114 by local oxidation of the exposed epitaxial silicon. In one example, the remaining silicon nitride layer is removed by a wet chemical removal step or other suitable technique. The LOCOS process forms the field relief dielectric layer 114 that extends into the top side of the starting semiconductor layer (e.g., below the starting top side in the orientation of FIG. 3) as well as outward along the third direction Z above the beginning top side. As shown in FIG. 3, moreover, the LOCOS field relief dielectric layer 114 has tapered lateral edges, referred to as bird's beaks that extend along the first direction X toward the prospective drain and source portions of the semiconductor layer. In one example the LOCOS field relief dielectric layer 114 has a maximum thickness along the third direction Z of approximately 50 to 150 nm.

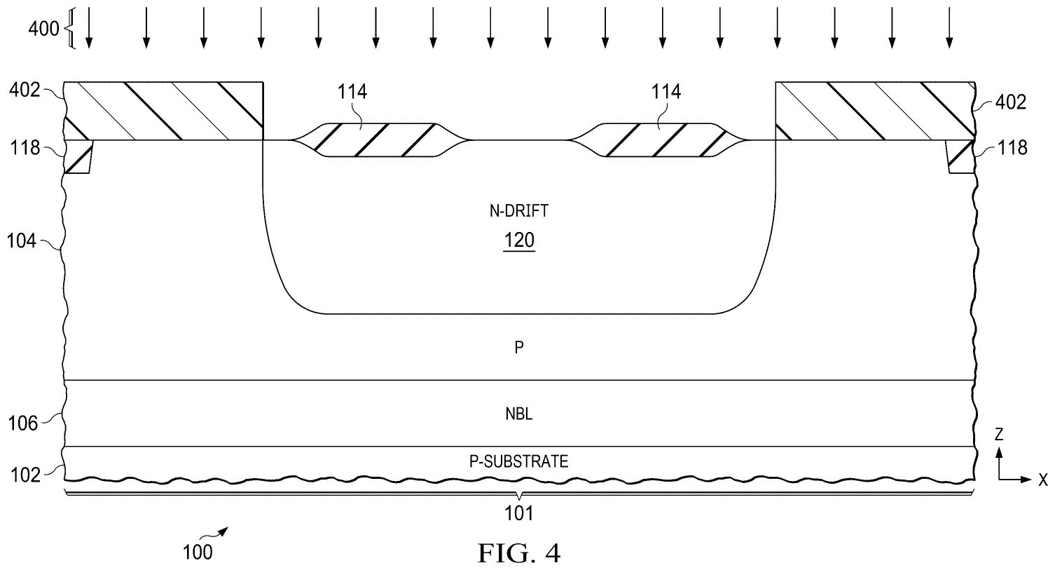

The method 200 continues at 210 in FIG. 2 with forming the drain drift region 120 having the second conductivity type (e.g., n-type), which can also be referred to as the drift region 120 under the field relief dielectric layer 114. FIG. 4 shows one example, in which a photomask 402 is deposited and patterned with an opening that exposes the prospective drift region and the field relief dielectric layer 114. An implantation process 400 is performed that forms the n-type drift region 120 by implanting phosphorus or other n-type dopants or impurities. In one example, the implantation process 400 includes four implants with an initial shallow implantation of phosphorous dopants at a first implantation energy of approximately 30 to 70 keV and a shallow implantation of arsenic at an implantation energy of approximately 30 to 70 keV, followed by a median implantation of phosphorus or arsenic at approximately 100 to 200 keV and a high energy phosphorus or arsenic implant at approximately 300 to 500 keV, where the implantation dose and energy can vary according to a voltage rating of a particular device.

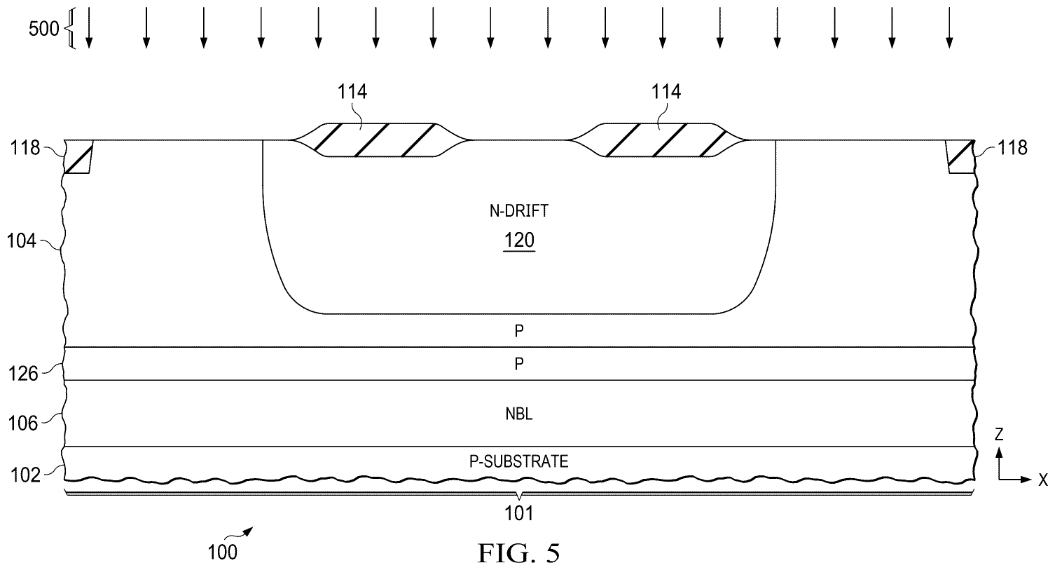

The method 200 in one example continues at 212 in FIG. 2 with implanting the p-type buried layer 126. FIG. 5 shows one example, in which an implantation process 500 is performed that implants boron or other p-type dopants at a high-energy to form the buried layer 126 by adding p-dopants to the p-type semiconductor layer 104 over the n-type buried layer 106. In one example, the process 500 implants boron at a dose from 1×10¹² cm⁻² to 1×10¹³ cm⁻² at an energy of 400 keV to 3 MeV. In another example, the process 500 can implant Indium or other p-type dopants. In certain implementations for low-voltage transistors, the implantation process 500 is a blanket implantation without any implant mask. In another implementation for high voltage transistors, an implant mask can be used for selective implantation of the buried layer 126. In one example, the implantation 500 can be followed by a thermal process to extend or diffuse the implanted p-type dopants below the drift region 120 The PBL implant 125 is followed by a thermal process (not specifically shown) which extends the PBL implant 125 below the drift region and thermal processing can be used to activate the implanted p-type dopants, or subsequent thermal processing can be used for dopant activation (e.g., a damage anneal after implanting shallow n and/or p wells such as shallow well 130 in FIG. 1 above). In other implementations, the p-type buried layer 126 and the processing at 212 can be omitted.

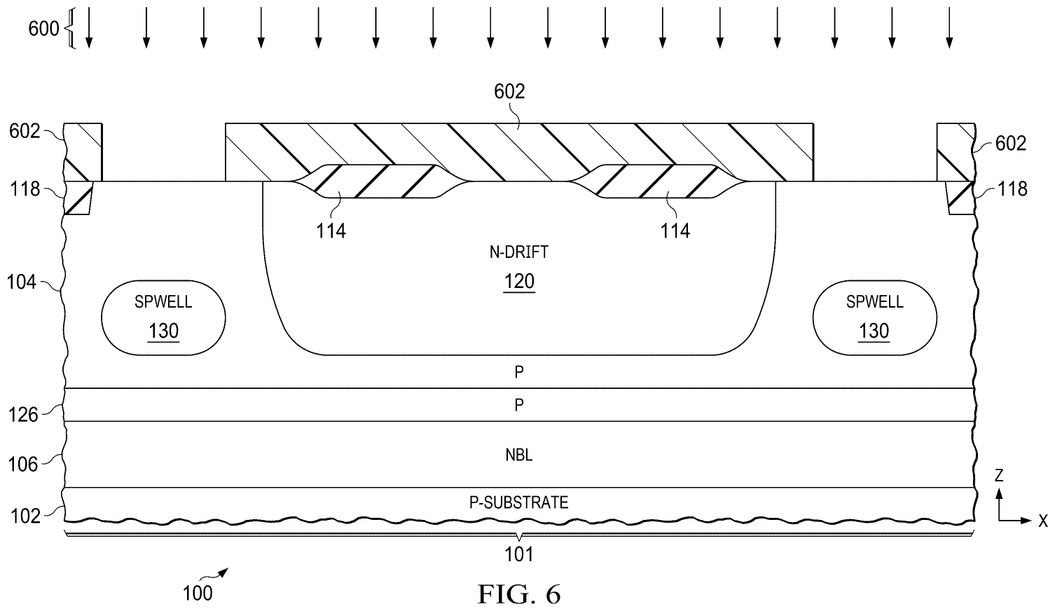

The method 200 continues at 214 in FIG. 2 with forming the shallow well 130. FIG. 6 shows one example, in which an implantation process 600 is performed using an implant mask 602. In one example, the process 600 forms the shallow well 130 (e.g., labeled SPWELL) can include two or more SPWELL implants, all at different energies. The implantation process 600 implants select portions of the body region 104 to increase the base doping level to suppress a parasitic lateral NPN bipolar transistor formed by N+ source-p-body-N+ drain. The parasitic NPN bipolar transistor, if activated, limits high current operation for the LDMOS transistor 101 restricting a safe operating area (SOA) of the LDMOS transistor 101.

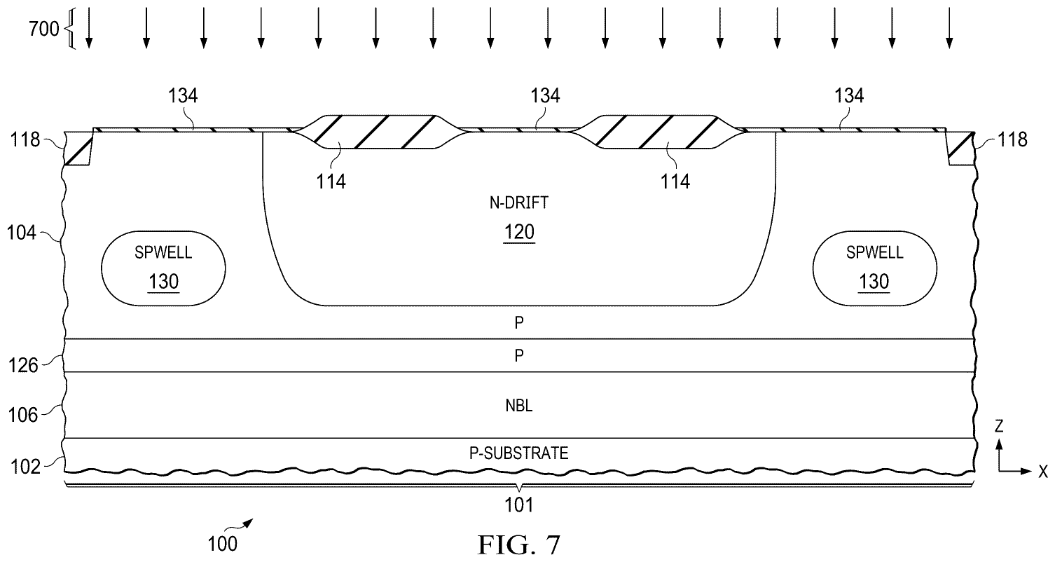

The method 200 continues at 216 in FIG. 2 with forming the gate dielectric layer 134 over the body region 104 and extending over the junction or interface between the body region 104 and the drain drift region 120. FIG. 7 shows one example, in which a gate dielectric formation process 700 is performed that forms the gate dielectric layer 134 by thermal oxidation or other suitable processing, such as a high temperature furnace operation or a rapid thermal anneal (RTA) process. The gate dielectric layer 134 thickness in one example is approximately 3 nm to 15 nm for silicon dioxide or a silicon oxynitride (SiON) gate dielectric layer 134 can be formed that is slightly thinner but with a higher dielectric constant than that of silicon dioxide, which is about 3.9, by way of example.

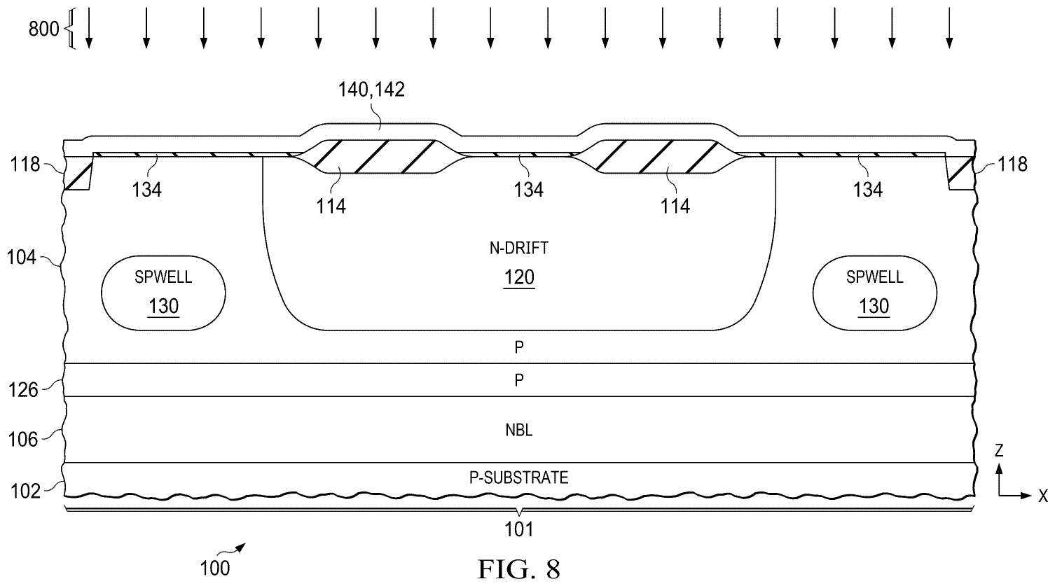

The method 200 continues at 218 to form the gate electrode and the floating field plate. FIG. 8 shows one example, in which a deposition process 800 is performed that forms a polycrystalline silicon (e.g., polysilicon) layer labeled 140, 142 over the top side of the wafer including the STI portions 118, the gate dielectric layer 134, the field relief dielectric layer 114 and the top side of the semiconductor layer including the body region 104 and the drift region 120. In one example, the process 800 includes one or more silane based precursors to form the polycrystalline silicon layer 140, 142. In other examples, a metal gate or CMOS-based replacement gate electrode process can also be used to provide the gate electrode layer 140, 142. In the illustrated example, the deposited layer 140, 142 is subsequently patterned to form both the gate electrode 140 and the floating field plate 142. In another implementation (not shown), the gate electrode 140 and the field plate 142 can be separately formed.

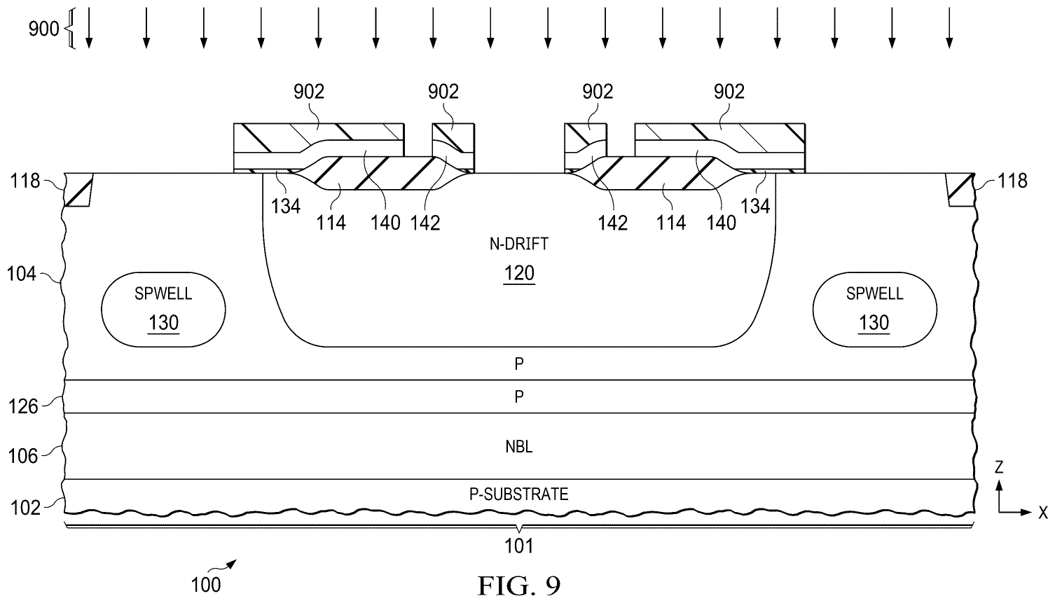

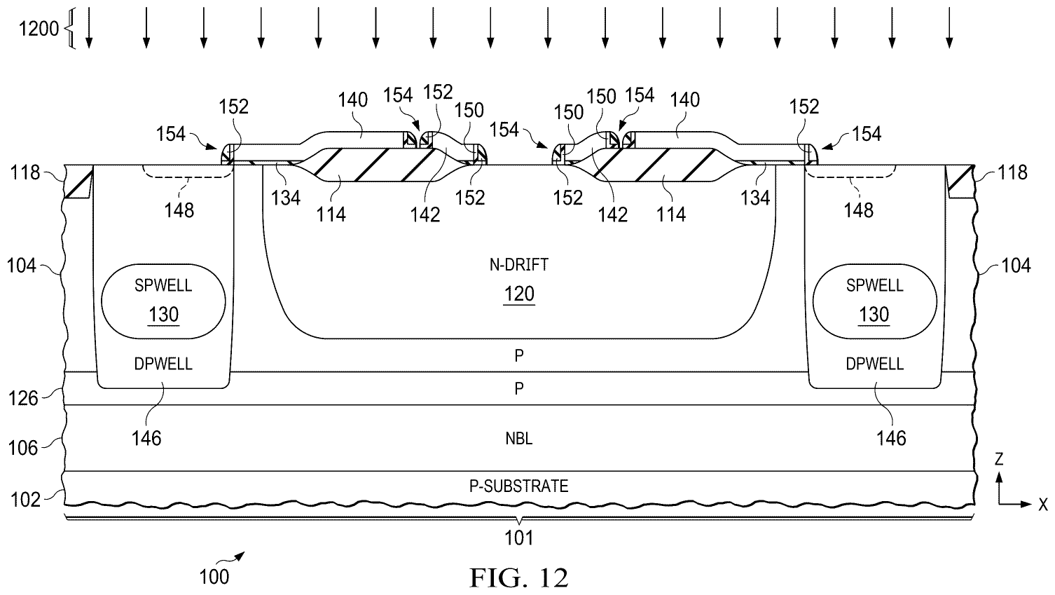

The deposited polysilicon in one example is patterned at 220 in FIG. 2. FIG. 9 shows one example, in which an etch process 900 (e.g., a plasma etch) is performed using an etch mask 902 that covers the prospective gate electrode 140 and field plate 142 to selectively remove the uncovered polysilicon and define the gate electrode 140 over the gate dielectric layer 134 and the field plate 142 located over the field relief dielectric layer 114 and spaced apart from the gate electrode 140. After the plasma etch process 900 in one example, the etch mask 902 is removed and a wet or dry process is used to clean the wafer surface. In one example, the mask formation and the etch process 900 define a space between the gate electrode 140 and the floating field plate 142 of between 200 nm and 600 nm or other suitable distance. In some examples, the space between the gate electrode 140 and the floating field plate 142 may be determined to preclude merging of subsequently formed sidewall spacers during later processing—e.g., as shown in FIG. 12. In other examples, the space between the gate electrode 140 and the floating field plate 142 may be determined to facilitate merging of subsequently formed sidewall spacers during later processing. In this or another example, a polysilicon critical dimension of between 100 nm and 300 nm for the field plate 142 is used. The gate dielectric layer 134 extends over a channel region of the LDMOS transistor 101. The channel region extends partway over the NDRIFT drift region 120, and partway over the body region 104. In the illustrated example the field plate 142 extends over one tapered end of the field relief dielectric layer 114 towards the prospective drain region.

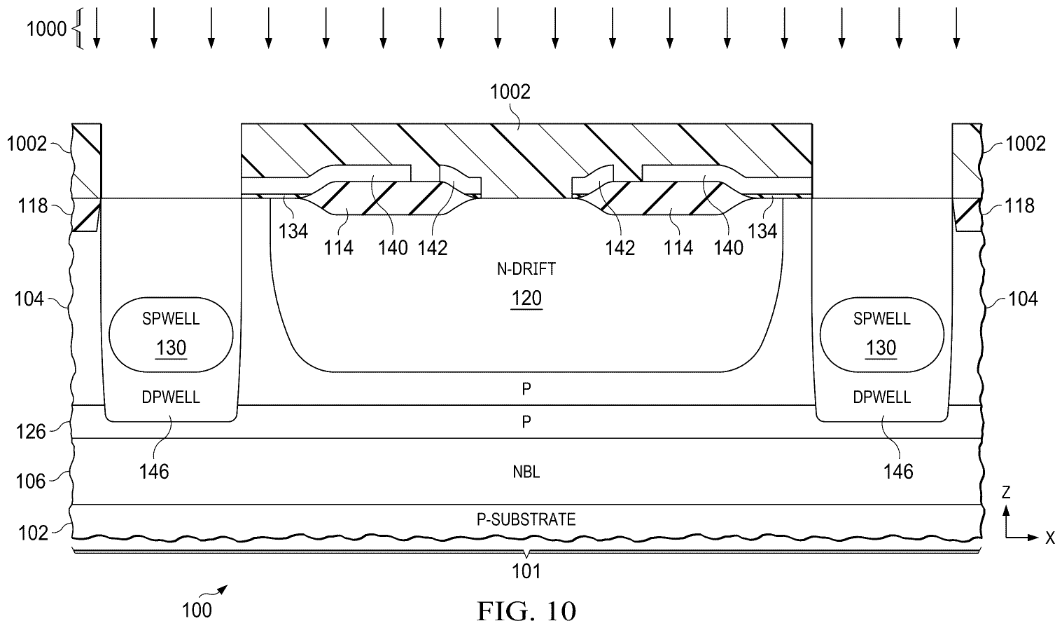

The method 200 continues at 222 in FIG. 2 with implanting the p-type deep well region 146. FIG. 10 shows one example, in which an implantation process 1000 is performed using an implant mask 1002. In one example, the implantation process 1000 implants p-type dopants into a portion of the body region 104 laterally adjacent to or outward of the implanted drift region 120 to form the p-type deep well region 146 (labeled DPWELL). The p-type dopants implanted by the process 1000 may include boron, indium or other suitable p-type dopants, where a boron implantation can be similar in energy to energies used to form p-type source/drain regions or p-type lightly doped drain regions in a semiconductor device process at a suitable dose to enable formation of a channel laterally and to suppress body NPN effects during operation of the LDMOS transistor 101. In one example, a boron implant with an energy of 20 keV, a dose of 8×10¹³ cm⁻² to 3.0×10¹⁴ cm⁻², such as approximately 1.5×10¹⁴ cm², and an angled implant can be used such as at a tilt angle of less than 5 degrees, such as 2 degrees. In another example, the DPWELL implantation at 222 can include a shallow implant with a boron dose of approximately 1×10¹⁴ cm⁻² at an implant energy of approximately 30 keV, an arsenic implant with a dose of approximately 1×10¹⁵ cm⁻² at an implant energy of approximately 30 keV and a high energy arsenic implant with a dose of approximately 1×10¹³ cm⁻² at an implant energy of approximately 600 keV to 1400 keV depending on a device rating.

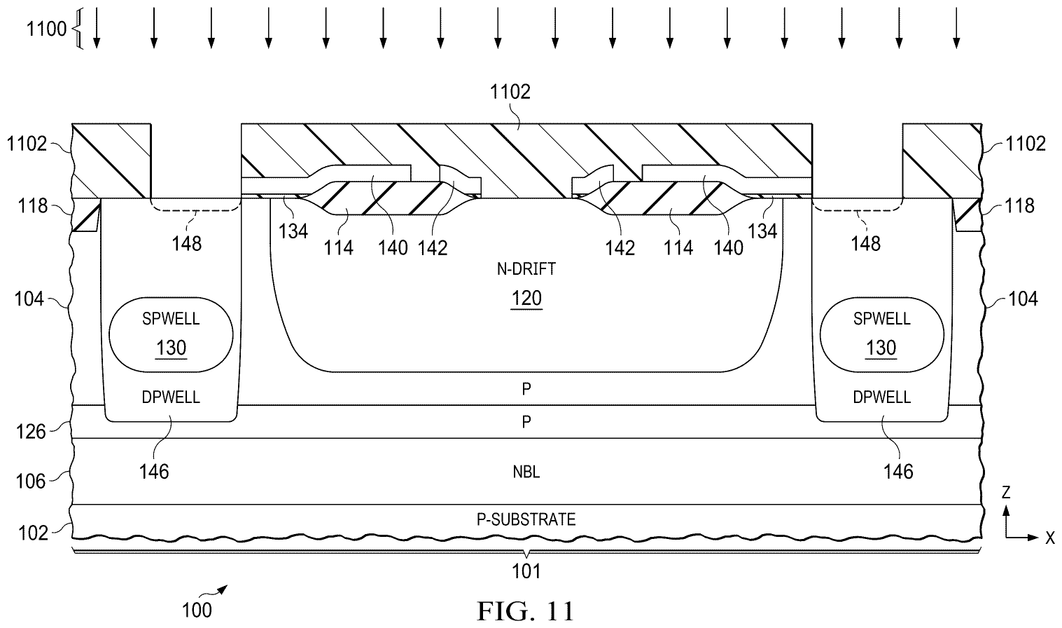

The method 200 continues at 224 in FIG. 2 with implanting the n-type deep well (DWELL) region 148. FIG. 11 shows one example, in which an implantation process 1100 is performed using an implant mask 1102. The process 1100 in one example implants n-type dopants such as phosphorus, arsenic or antimony to a source side of the LDMOS transistor 101 to form an n-type DWELL region 148. In one example, the process 1100 implants arsenic with a dose 5×10¹³ cm⁻² to 1.2×10¹⁵ cm⁻² (e.g., 8×10¹⁴ cm⁻²) an energy 10 keV to 50 keV (e.g., 15 keV and a 15 degree ion implant tilt angle), or some or all of this implant can be performed at a steeper tilt angle such as approximately 45° for 2 or 4 rotations. The implant angle can also be straight as well (at 0 degrees tilt) or from zero to 45 degrees. An arsenic implant energy of about 15 keV can allow the arsenic to penetrate through the gate dielectric layer 134 (e.g., when a 5V oxide is used for gate dielectric) adjacent to the gate electrode 140 which reduces the net doping concentration there by counter doping so as to reduce gate-induced parametric shifts. The 15 degree or so arsenic implant angle can reduce the channel voltage threshold (Vt) without reducing the p-type DPWELL region 146 implant dose, enabling the simultaneous improvement of Vt and control of the body doping of the parasitic NPN. After the implantation process 1100 in one example, a polysilicon oxidation process (not shown) can be performed to reduce gate-to-drain capacitance (CGD) and gate-to-source capacitance (CGS). The polysilicon oxidation also provides the thermal budget for the DPWELL boron dopant to diffuse past the DPWELL arsenic, forming the channel profile in the lateral direction and putting some P+ type silicon under the source to suppress lateral NPN breakdown effects during high power operation. After the polysilicon oxidation, lightly doped drain (LDD) implants can be patterned, implanted (not specifically shown) followed by activation of the dopants by a rapid thermal process (RTP).

The method 200 continues at 226 with sidewall spacer formation for the field plate 142 and the gate electrode structures 140. FIG. 12 shows one example, in which a process 1200 is performed that forms the sidewall spacers 154 along the lateral sides of the gate electrode 140 and the lateral sides of the floating field plate 142. In one example, an oxide layer 150 and a nitride layer 152 are deposited over the entire wafer surface, followed by a blanket anisotropic plasma etch process that removes portions of the oxide layer 150 and portions of the nitride layer 152, to form the sidewall spacers 154 of dielectric material on the gate electrode 140 and on the floating field plate 142. The sidewall spacer 154 in one example overlaps an edge of the field relief dielectric layer 114 adjacent to the drain region. In another example, the nitride layer 152 may be deposited across the surface of the wafer and etched to form a nitride-only sidewall spacer 154.

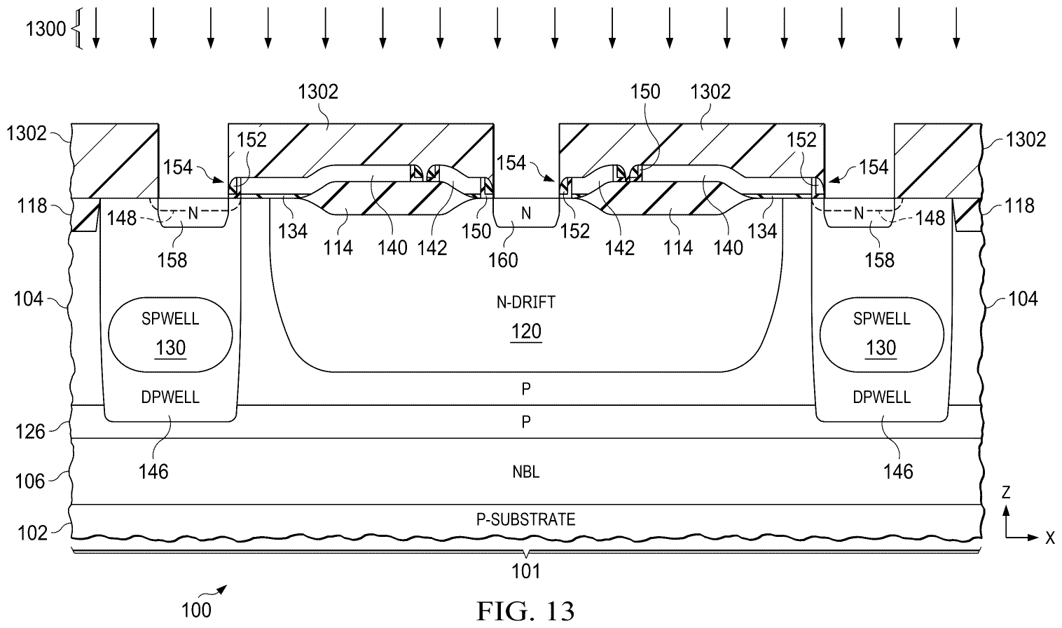

The method 200 continues at 228 with implanting the source region 158 and the drain region 160 of the body region 104 with dopants of the second conductivity type (e.g., n-type). FIG. 13 shows one example, in which an implantation process 1300 is performed with an implant mask 1302 to implant the source region 158 in the p-type DPWELL region 146, and to implant the drain region 160 in the drain drift region 120. The ion implantation process 1300 in one example uses an edge of the sidewall spacer 154 to self-align the drain region 160 to the floating field plate 142. The drain region 160 in one example contains an average dopant density at least twice that of the drain drift region 120. The floating field plate 142 extends between the drain region 160 and the gate electrode 140 over a distance that is greater than twice the thickness of the field relief dielectric layer 114. Also, in the illustrated example the floating field plate 142 overlaps the bird's beak of the drain-side of the field relief dielectric layer 114 and is spaced apart from the drain region 160 by the sidewall spacer 154.

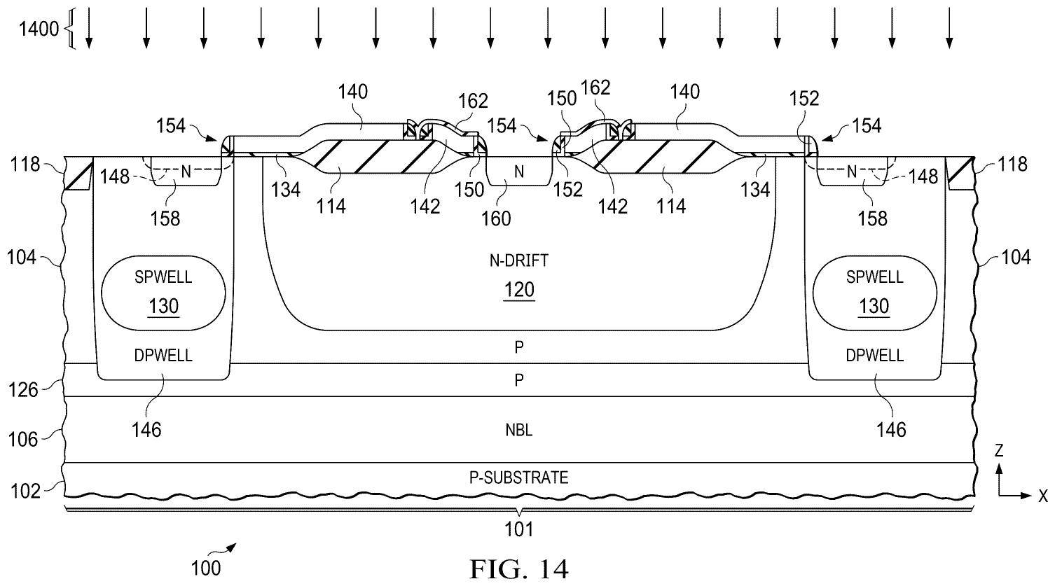

The method 200 may continue at 230 with forming the silicide blocking layer 162 at select locations. For example, the silicide blocking layer 162 may cover the entire top side of the field plate 142 and extending between the field plate 142 and the gate electrode 140 along the tops and valley between the respective sidewall spacers 154 as shown in FIG. 14. FIG. 14 shows a process 1400 performed to form the silicide blocking layer 162 that is subsequently patterned. In one example, the silicide blocking layer 162 can be formed by depositing one or more sublayers of an oxide, a nitride, an oxynitride, or any combination thereof over the entire wafer. The silicide blocking layer 162 in this example is then patterned and one or more sublayers can be etched away to expose prospective portions to be silicided (e.g., where the metal silicide layer 165 is to be formed). The silicide blocking layer 162 may be allowed to remain in select areas on the body region 104 and the floating field plate 142 at the wafer surface where silicide is not intended to be formed. In at least one implementation, the silicide blocking layer 162 is not required for LDMOS formation and may be omitted.

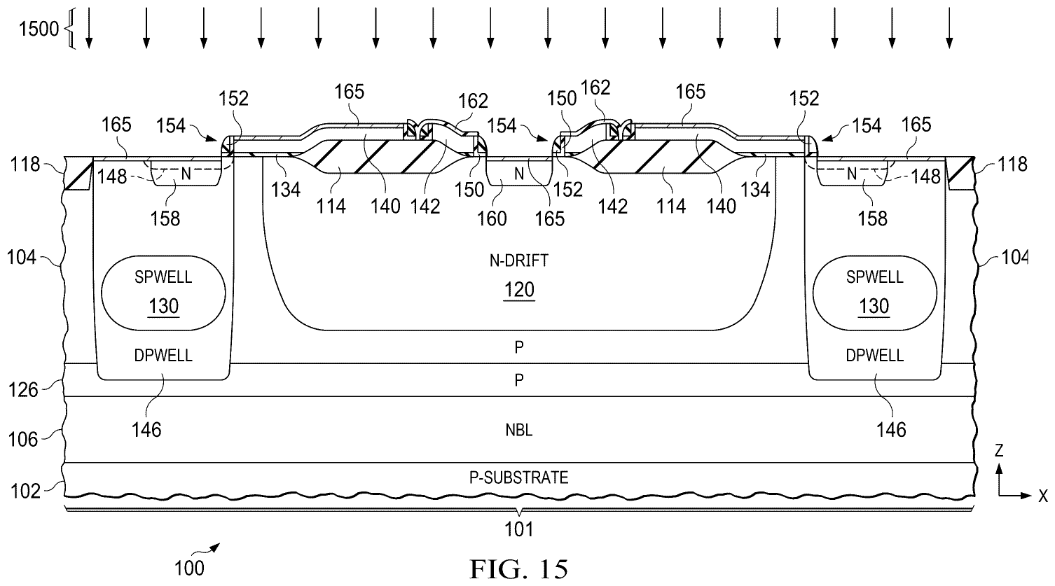

The method 200 continues at 232 with silicidation to form the metal silicide layer 165 in certain areas not covered by the silicide blocking layer 162. FIG. 15 shows one example, in which a metal silicide process 1500 is performed that forms the metal silicide layer 165. In one example, a metal layer (not shown) is deposited, for example, using a blanket deposition process (not shown). The semiconductor device 100 is heated to form the metal silicide layer 165 in exposed regions of the body region 104 and the gate electrode 140. Unreacted metal is subsequently removed in a wet stripping process (not shown). In some examples, the floating field plate 142 includes the metal silicide layer 165—e.g., when the silicide blocking layer 162 is removed from the floating field plate 142 or when the silicide blocking layer 162 formation is omitted.

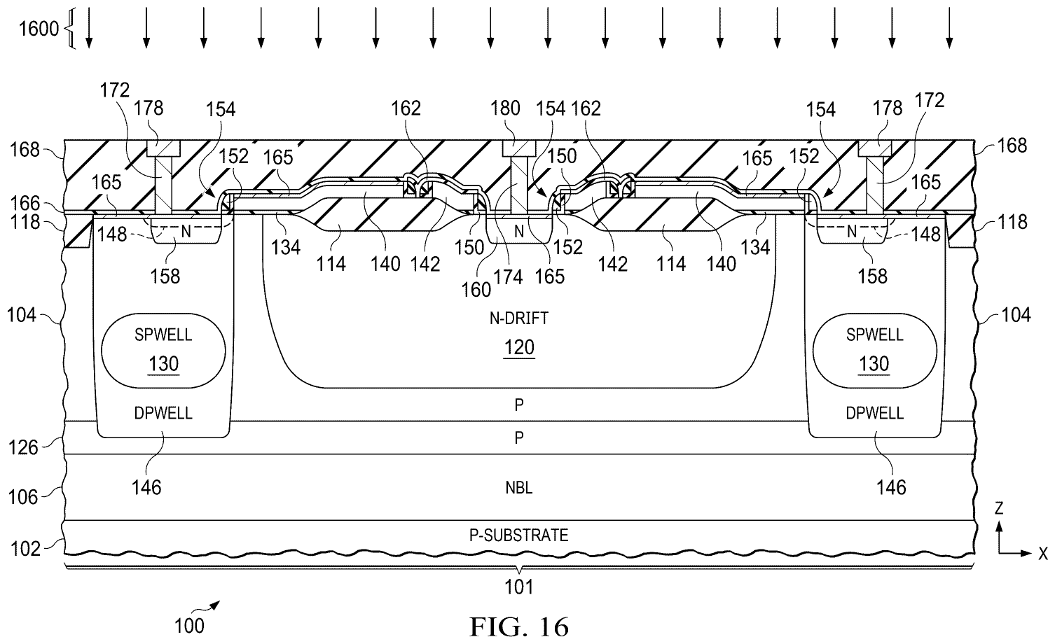

The method continues at 234 in FIG. 2 with formation of a nitride etch stop layer, PMD and contact formation, and further metallization. FIG. 16 shows one example, in which processing 1600 is performed that forms a single or multilevel metallization structure with contacts 172, 174, and 176 (FIG. 1A above) through the PMD dielectric layer 168 to respective source region 158, drain region 160, and gate electrode 140, while forming no contact to the field plate 142. The finished wafer can then be separated (e.g., die singulation) to separate individual semiconductor dies from the starting wafer, and the dies can then be packaged to form integrated circuits or other packaged semiconductor devices.

Referring also to FIGS. 17-23, the floating field plate 142 provides performance and reliability advantages for drain extended transistors while allowing dimension reduction such as half pitch without any or significant tradeoff in terms of CHC injection, Idlin reduction, or breakdown voltage performance. FIG. 17 shows a semiconductor device 1700 having a floating field plate 142 in an LDMOS transistor generally as described above in connection with FIGS. 1 and 1A. The semiconductor device 1700 includes an interface 1701 between silicon and silicon dioxide—e.g., silicon of the drain drift region 120 and silicon dioxide of the field relief dielectric layer 114. FIG. 17 also shows a graph 1710 of interface trap generation ΔNᵢₜ per cm² indicating simulated numbers of hot carrier traps generated at the interface 1701 as a function of distance along the first direction X. The graph 1710 includes a curve 1711 of simulated carrier traps generated for the drain field plate tied to the drain voltage and a curve 1712 for the floating drain field plate 142. As the distance along the first direction X increases from left to right in the graph 1710 (e.g., from the source side towards the drain), the number of hot carrier traps generated at the interface 1701 (ΔNᵢₜ per cm²) is significantly lower for the floating field plate 142 (curve 1712) than for the case where the field plate is tied to the drain voltage VD (curve 1711).

The floating field plate 142 provides significant advantages in mitigating or preventing interface trap generation along the interface 1701 and facilitates improved device reliability and reduced linear mode drain current shifting or reduction during operation of the drain extended transistor. The floating field plate 142 facilitates improved CHC lifetime, which may be manifested as reduced linear drain current shifting due to reduced interface trap generation at the interface 1701 (e.g., the interface between the silicon drain drift region 120 and the silicon dioxide of the field relief dielectric layer 114), with significantly less interface traps formed near the drain.

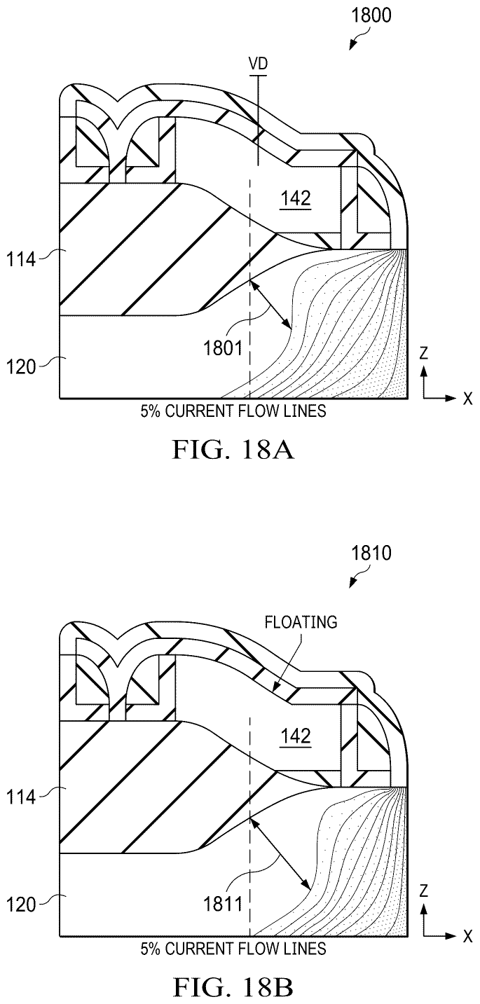

FIG. 18A shows a 5% current flow line simulation 1800 of a drain extended transistor with a drain field plate 142 tied to the drain voltage VD and FIG. 18B shows a 5% current flow line simulation 1810 of the drain extended transistor 101 with the floating field plate 142, where the individual simulated current flow lines in the drain drift region 120 represent regions where 5% of the drain current flows. The simulation 1800 for the case where the field plate 142 is tied to the drain voltage VD show significantly higher current crowding with a smaller space 1801 in the drain drift region near the interface 1701 (as marked by the length of the arrow in FIG. 18A) at a reference distance line (dashed vertical line in FIG. 18A) when compared to the simulation 1810.

The simulation 1810 in FIG. 18B shows significantly less current crowding in the drain drift region at the same reference distance line, where the corresponding space 1811 in the drain drift region near the interface 1701 (as marked by the length of the arrow in FIG. 18B) is significantly greater than the space 1801 in FIG. 18A. The floating field plate 142 in FIG. 18B advantageously reduces the current crowding near the interface 1701 to mitigate channel hot carrier injection trapping in the field relief dielectric layer 114 and mitigates linear drain current shift to promote better device reliability.

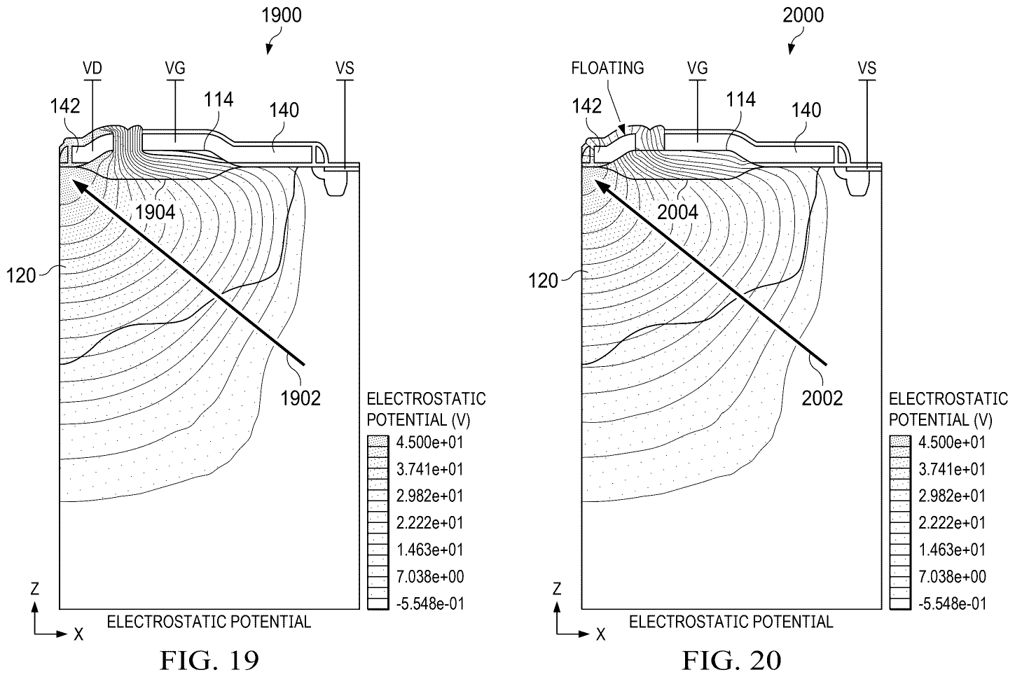

FIGS. 19 and 20 show comparative electrostatic potential simulations for drain extended transistors. FIG. 19 shows an electrostatic potential simulation 1900 of a drain extended transistor with a drain field plate 142 biased to the drain voltage VD with the simulated electrostatic potential increasing along the direction of an arrow labeled 1902. FIG. 19 further indicates a line 1904 showing the interface between the field relief dielectric layer 114 and the drain drift region 120—e.g., the interface 1701.

FIG. 20 shows an electrostatic potential simulation 2000 of the drain extended transistor 101 with the floating drain field plate 142 with simulated electrostatic potential increasing along the direction of an arrow labeled 2002. FIG. 20 further shows a line 2004 indicating the interface between the field relief dielectric layer 114 and the drain drift region 120—e.g., the interface 1701. Comparing the simulations 1900 and 2000 of FIGS. 19 and 20, the electrostatic potential is significantly reduced around the floating field plate 142 in FIG. 20 compared with the electrostatic potential at the interface 1904 near the drain and the drain field plate 142 with the drain field plate 142 connected to the drain voltage as shown in FIG. 19.

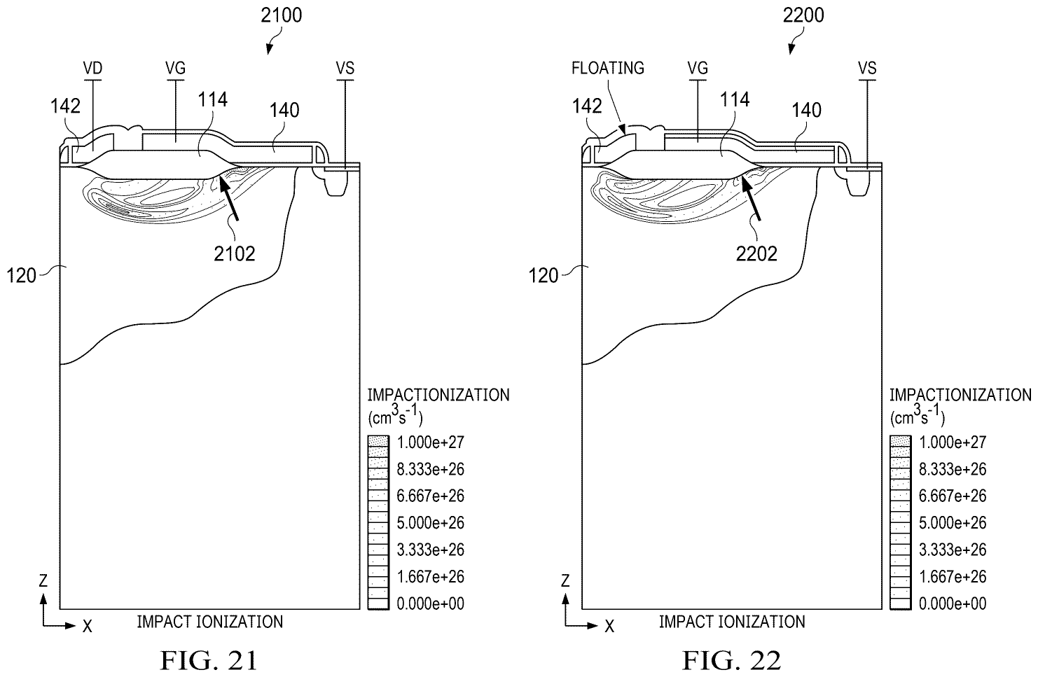

FIG. 21 shows an impact ionization simulation 2100 in cm⁻³ per second of a drain extended transistor with a drain field plate 142 biased to the drain voltage VD with the impact ionization increasing along the direction of an arrow labeled 2102. FIG. 22 shows an impact ionization simulation 2200 of the drain extended transistor 101 with a floating drain field plate 142 with the impact ionization increasing along the direction of an arrow labeled 2202. The simulation 2100 with the field plate 142 at the drain voltage shows significantly larger areas of high impact ionization along the interface between the field relief dielectric layer 114 and the drain drift region 120—e.g., the interface 1701. The area along the interface with high impact ionization is relatively smaller in the simulation 2200 of the drain extended transistor 101 with a floating drain field plate 142 in FIG. 22. The lower impact ionization, which will lead to less electron-hole pair generation, is expected to result in reduced channel hot carrier injection.

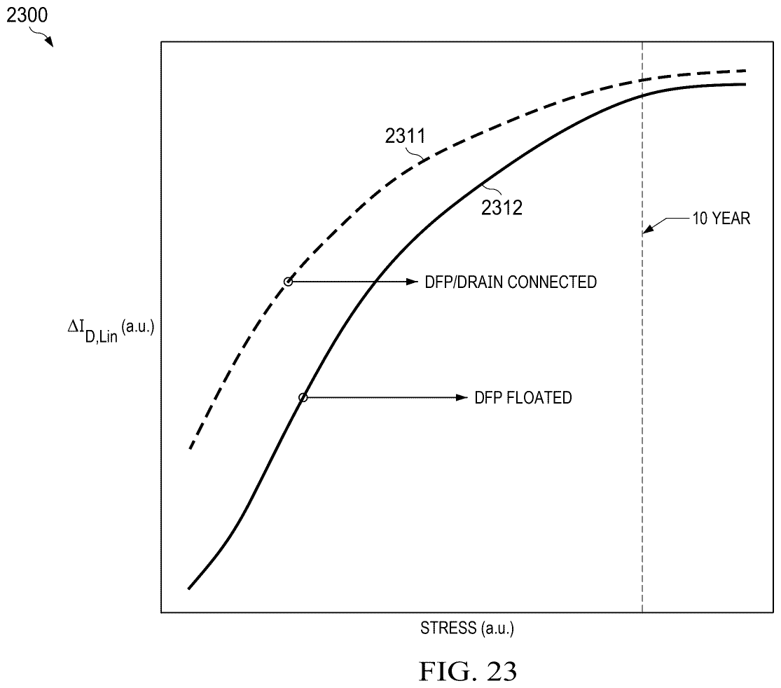

FIG. 23 shows a graph 2300 of linear mode drain current shift ΔI_{D,Lin} as a percentage for an implementation of the LDMOS transistor 101 of FIGS. 1 and 1A with the drain field plates tied to the drain voltage VD and floated as a function of electrical stress time, including a line representing 10 years of operation. A first curve 2311 in the graph 2300 shows simulated percentage shift for the transistor with the drain field plate 142 tied to the drain voltage VD. A second curve 2312 in the graph 2300 shows simulated percentage shift for the transistor with the drain field plate 142 floating. The floating field plate 142 (curve 2312) significantly reduces the linear mode drain current shift ΔI_{D,Lin} compared to the use of the field plate biased to the drain voltage VD (curve 2311) and shows improvement in channel hot carrier injection beyond the 10-year lifetime.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A semiconductor device, comprising:
a semiconductor layer over a semiconductor substrate, the semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region;
a field relief dielectric layer over the drain drift region, the field relief dielectric layer extending from the gate dielectric layer toward the drain region and having a thickness greater than the gate dielectric layer; and
a field plate located over the field relief dielectric layer and between the gate electrode and the drain region, the field plate floating.

2. The semiconductor device of claim 1, wherein the field plate follows a path that has rounded corners with radii greater than a thickness of the field plate.

3. The semiconductor device of claim 1, further comprising a silicide blocking layer covering an entire top side of the field plate.

4. The semiconductor device of claim 1, wherein the field relief dielectric layer includes a local oxidation of silicon (LOCOS) layer of silicon dioxide, and the field plate is located over a point at which the LOCOS layer ends at a top surface of the semiconductor layer.

5. The semiconductor device of claim 1, wherein the gate electrode extends over the field relief dielectric layer and is spaced apart from the field plate by a silicide blocking layer.

6. The semiconductor device of claim 1, wherein the field plate includes polycrystalline silicon.

7. The semiconductor device of claim 1, wherein the field plate extends between the drain region and the gate by a distance that is at least twice a thickness of the field relief dielectric layer.

8. The semiconductor device of claim 1, wherein the field plate extends over a tapered edge of the field relief dielectric layer.

9. The semiconductor device of claim 1, wherein a sidewall spacer on a sidewall of the field plate extends to the drain region.

10. A semiconductor device, comprising:
a semiconductor layer over a semiconductor substrate, the semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region;
a field relief dielectric layer over the drain drift region, the field relief dielectric layer extending from the gate dielectric layer toward the drain region and having a thickness greater than the gate dielectric layer; and
a field plate located over the field relief dielectric layer and between the gate electrode and the drain region, the field plate spaced apart from the gate electrode;
wherein the field plate is not conductively connected to any other structure.

11. The semiconductor device of claim 10, wherein the gate electrode extends over the field relief dielectric layer and is spaced apart from the field plate by a silicide blocking layer.

12. The semiconductor device of claim 10, wherein the field plate extends between the drain region and the gate by a distance that is at least twice a thickness of the field relief dielectric layer.

13. The semiconductor device of claim 10, wherein the field plate extends over a tapered edge of the field relief dielectric layer.

14. The semiconductor device of claim 10, further comprising a sidewall spacer that is located on a sidewall of the field plate and extends to the drain region.

15. The semiconductor device of claim 10, further comprising a silicide blocking layer that covers an entire top side of the field plate.

16. The semiconductor device of claim 10, wherein the field plate is electrically isolated from the gate electrode and from the drain region.

17. A method of fabricating a semiconductor device, the method comprising:
forming a body region having a first conductivity type in a semiconductor layer over a semiconductor substrate;
forming a field relief dielectric layer over the body region;
forming a drain drift region having a second, opposite, conductivity type under the field relief dielectric layer;
forming a gate dielectric layer over the body region and extending over a junction between the body region and the drain drift region;
forming a polysilicon layer over the gate dielectric layer and over the field relief dielectric layer;
patterning the polysilicon layer to form a gate electrode over the gate dielectric layer and a field plate located over the field relief dielectric layer and spaced apart from the gate electrode;
implanting a source region and a drain region of the body region with dopants of the second conductivity type; and
forming electrically conductive contacts to the gate electrode and to the source and drain regions without forming any electrical connection to the field plate.

18. The method of claim 17, further comprising forming a metallization structure with contacts to the gate electrode, the source region, and the drain region and no contact to the field plate.

19. The method of claim 18, further comprising forming a silicide blocking layer covering an entire top side of the field plate and extending between the field plate and the gate electrode.

20. The method of claim 18, wherein forming the field relief dielectric layer includes performing a local oxidation of silicon (LOCOS) process.
